(19) United States
(12) Patent Application Publication
(10) Pub. No.: US 2024/0322522 A1
(43) Pub. Date: Sep. 26, 2024

(54) METHOD FOR OPERATING A FREQUENCY AGILE TUNABLE SELF-INJECTION LOCKING LASER SYSTEM AND SELF-INJECTION LOCKING LASER SYSTEM

(71) Applicants: ECOLE POLYTECHNIQUE FEDERALE DE LAUSANNE (EPFL), Lausanne (CH); PURDUE RESEARCH FOUNDATION, West Lafayette, IN (US)

(72) Inventors: Tobias Kippenberg, Aran (CH); Sunil Bhave, West Lafayette, IN (US); Hao Tian, West Lafayette, IN (US); Johann Riemensberger, St-Sulpice VD (CH); Grigorii Likhachev, Chavannes-Renens (CH); Anat Siddharth, Bussigny (CH)

(73) Assignees: ECOLE POLYTECHNIQUE FEDERALE DE LAUSANNE (EPFL), Lausanne (CH); PURDUE RESEARCH FOUNDATION, West Lafayette, IN (US)

(21) Appl. No.: 18/654,421

(22) PCT Filed: Nov. 4, 2021
(86) PCT No.: PCT/EP2021/080646

§ 371 Date: May 3, 2024

(51) Int. Cl. H01S 5/065; H01S 5/068; H01S 5/0687

(52) U.S. Cl. CPC H01S 5/0656; H01S 5/06808; H01S 5/0687

(57) ABSTRACT

A frequency agile tunable self-injection locking laser system being formed by a laser device coupled to at least one optical resonator and method and controller therefor are disclosed. A diode current and an optical resonator are controllable. A self-injection locking range is selected and the self-injection locking range corresponds an optical feedback phase for back-reflected light from the optical resonator into the laser device. A diode current is set and a maximum tuning range of the actuation voltage in which self-injection locking is maintained is determined. The laser system is operated with actuation voltages in a range depending on the determined tuning range.

This invention was made with government support under PHY 1839164 awarded by the National Science Foundation. The government has certain rights in the invention.

### TECHNICAL FIELD

The present invention generally relates to tunable self-injection locking laser systems and methods for tuning such a laser system for frequency agile operation.

### TECHNICAL BACKGROUND

Lasers are imperative in a wide range of technological and scientific applications, ranging from distributed fiber sensing, coherent LiDAR, high spectral efficiency coherent communication, or microwave photonics. Requirements for these applications are low phase noise and high-frequency agility. Frequency-agility is a key requirement, e. g., to lock lasers to fiber gratings, adjust the phase in carrier recovery, or achieve tight phase locking.

Over the past decade, the development of heterogeneously integrated lasers has led to a new class of CMOS compatible highly integrated lasers sources, that are now commercially employed in data-center interconnects. Fundamentally, the linewidth, that is phase noise, of lasers is given by the Schawlow-Townes linewidth limit, which dictates that low-loss laser cavities allow inherently low phase noise. To date, the lowest laser phase noise of compact semiconductor lasers is achieved by operating the laser in a self-injection-locking mode with discrete crystalline resonators or gain chips coupled to low-loss photonic lightwave circuits. These systems, however, have a very limited frequency agility, i.e. they lack fast and continuous mode-hop-free tuning capability.

The main difficulty in achieving high agility lies in rapid frequency tuning of the resonator/cavity that provides laser linewidth narrowing effect while maintaining a long photon lifetime in the resonator/cavity.

Increasingly, process technologies, such as silicon nitride (Si₃N₄) on Silicon, are more and more available which allows monolithic integration of photonic components in a single device. This enables a batch production of integrated photonic devices e. g. for laser systems with the lowest phase noises.

However, integrated photonic devices often suffer from a slow tunability limited by the thermal response time of integrated microheaters thus resulting in a lack of frequency agility.

From document, Warren Jin et al, “Piezoelectrically tuned silicon nitride ring resonator”, Optics EXPRESS Vol. 26, No 3, Feb. 5, 2018, a Si₃N₄ ring resonator is known which is tuned by geometric deformation using a piezoelectric actuator. Here, a photonic ring resonator and piezoelectric elements are monolithically integrated on a silicon substrate which allow ultra-low-power tuning across a full FSR in a low confinement silicon nitride-based ring resonator structure.

From document J. Riemensberger et al, “Massively parallel coherent laser ranging using soliton microcomb”, Nature (2020) a laser system is known, wherein by fast chirping of the pump laser in the soliton existence range of a microcomb with amplitudes of up to several gigahertz and a sweep rate of up to ten megahertz, a rapid frequency change occurs in the underlying carrier waveform of the soliton pulse stream, but the pulse-to-pulse repetition rate of the soliton pulse stream is retained.

From document J. Liu et al, “Monolithic piezoelectric control of soliton microcombs”, Nature (2020) discloses the ability to frequency-shift the optical comb spectrum via synchronous tuning of the independent pump laser and the micro-resonator. This enables a massively parallel frequency-modulated engine for lidar (light detection and ranging), with increased frequency excursion, lower power and elimination of channel distortions resulting from the soliton Raman self-frequency shift.

In document US 2020/0280173 A1 discloses a tunable solid state laser device comprising a semiconductor based gain chip; and a silicon photonic filter chip with tuning capability, wherein silicon photonic filter chip comprises an input-output silicon waveguide, at least two ring resonators formed with silicon waveguides, one or more connecting silicon waveguides interfacing with the ring resonators, a separate heater associated with each ring resonator, a temperature sensor configured to measure the chip temperature, and a controller connected to the temperature sensor and the separate heaters and programmed with a feedback loop to maintain the filter temperature to provide the tuned frequency, wherein the one or more connecting silicon waveguides are configured to redirect light resonant with each of the at least two ring resonators back through the input-output silicon waveguide, wherein the input-output silicon waveguide of the silicon photonic filter chip is coupled to the semiconductor based gain chip with a spot size convertor to provide for mode size matching to reduce loss due to the interface.

In document US 2009/0122817 A1 it is disclosed a variable-wavelength filter for varying a wavelength at which light is transmitted, comprising an optical circuit component for dividing light input from an external device into at least two ports; and a loop waveguide interconnecting at least said ports divided by said optical circuit component in the form of a loop, with at least two wavelength selecting filters inserted in series in a path of said loop waveguide, said wavelength selecting filters having periodic transmission characteristics on a frequency axis which are different from each other, and an asymmetrical Mach-Zehnder interferometer having periodic transmission characteristics on a frequency axis, at least one of said wavelength selecting filters being capable of varying a selected wavelength, the transmission characteristics of said asymmetrical Mach-Zehnder interferometer having a period which is represented by about the least common multiple of the periods of the transmission characteristics of said at least two wavelength selecting filters.

From document Doret, “Simple, low-noise piezo driver with feed-forward for broad tuning of external cavity diode lasers” (2018) a low-noise design for a piezo driver is known suitable for frequency tuning of bulk external-cavity diode laser. This simple driver improves upon many commercially available drivers by incorporating circuitry to produce a “feed-forward” signal appropriate for making simultaneous adjustments to the piezo voltage and laser current, enabling dramatic improvements in a mode-hop-free laser frequency tuning range.

In document Nayuki et al, “Continuous Wavelength Sweep of External Cavity 630 nm Laser Diode Without Antireflection Coating On Output Facet” (1998) a 630 nm AlGaInP laser diode is installed in a Littrow-type external cavity. In this cavity, the LD has the same effect as an etalon, and its free spectral range can be controlled easily by the LD drive current. By scanning the grating angle of the external cavity and LD drive current simultaneously, a single-mode oscillation and continuous wavelength sweep of over 22 GHz is obtained without mode hopping.

Document US 2018/0205463 A1 discloses a soliton generation apparatus comprising an optical resonator, a pumping laser for providing light at a pumping wavelength into the optical resonator, a generator for generating multiple solitons in the optical resonator, a detuning device for changing the wavelength detuning between the pumping laser wavelength and an optical resonance wavelength of the optical resonator to remove at least one soliton of the generated multiple solitons to provide (i) a plurality of solitons that comprises at least one less soliton than that of the generated multiple solitons or (ii) a single soliton in the optical resonator.

One mode of operation of a laser system with a DFB laser device (DFB: distributed feedback structure) which is coupled to an optical resonator is to modulate or to vary the laser frequency basically by controlling characteristics of the optical resonator. Using a piezo actuator with the optical resonator allows to stress-tune the resonator. The laser system may be operated to attain self-injection locking via the coupling of counter-propagating micro-resonator modes induced by Rayleigh backscattering. This operation mode is preferable to systems incorporating multiple coupling ports to the micro-resonator as lowest laser phase noise of compact semiconductor lasers can be achieved. This is because the lowest amount of external losses are induced in the micro-resonator which preserves the optical quality factor.

Basically, the variation of the piezo or electro-optical actuation allows to operate the laser device to output laser light within a bandwidth of frequencies of the self-injection locking mode. However, in self-injection locking only a very limited tuning range can be reached for modulating or varying the electro-optical or piezo actuation. Therefore, it is generally desirable to operate the laser system in self-injection locking mode while simultaneously having available an optimized/maximized bandwidth of possible output frequencies of laser light which can be reached within a tuning range of actuation voltages.

It is therefore an object of the present invention to provide a method for operating of a self-injection locking laser system in a frequency agile operation mode which allows a large tuning range for frequency modulation.

### SUMMARY OF THE INVENTION

These objectives have been resolved with a method for operating a frequency agile tunable self-injection locking laser device according to claim 1 and the self-injection locking laser system according to the further independent claim.

Preferred embodiments are indicated in the dependent sub-claims.

According to a first aspect, a method is provided for operating a frequency agile tunable self-injection locking laser system being formed by a laser device coupled to at least one optical resonator, wherein a diode current of a laser diode of the laser device is controllable and wherein the optical resonator is controllable by controlling a piezo or an electro-optical actuator configured to apply a variation of the refractive index of a resonator material through mechanical stress or an electric displacement field, respectively, at least partially onto the at least one optical resonator depending on an actuation voltage, inducing a change in the effective optical path length of the optical resonator, comprising the steps of:
selecting a self-injection locking range among a plurality of self-injection locking ranges by varying the diode current and monitoring self-injection locking ranges, wherein self-injection locking ranges corresponding to current ranges in which self-injection locking occurs, wherein the self-injection locking corresponds to an optical feedback phase for back-reflected light from the at least one optical resonator into the laser device,
setting the diode current to a value selected from the current range of the selected self-injection locking mode;
determining a maximum tuning range of the actuation voltage in which self-injection locking is maintained;
operating the laser system with actuation voltages in a range depending on the determined maximum tuning range.

Moreover, the self-injection locking range may be selected as the self-injection locking range resulting in the largest bandwidth of self-injection locking, where the laser frequency is locked to a frequency of a cavity resonance.

It may be provided that for setting the diode current, the diode current is selected from a central range between the current limits of the selected self-injection locking range, wherein the set as a mean current of the current limits of the selected self-injection locking range. The self-injection locking range can vary depending on the direction of tuning. In this case the mean current may be selected from a central range between the current limits of both tuning directions such as to maximize the tuning range of the laser in the self-injection locked regime.

Above method for operating a laser system is carried out with a laser system e.g. having a DFB laser device (DFB: distributed feedback structure) which is coupled to an optical resonator. The above optical resonator device may be formed as a compact dielectric resonator having a cm or sub-cm scale optical path length. The optical resonator may comprise a circular resonator like a ring or loop resonator, a Fabry-Perot resonator (linear resonator) or the like.

In an alternative embodiment, the laser system may comprise a DBR laser device (DBR: distributed Bragg reflector) or a Fabry-Perot type laser device.

The resonator may be coupled with a piezo actuator so as to apply mechanical stress onto the dielectric resonator. The stress induces a strain field and a geometric deformation.

The strain field and the geometric deformation induce changes of an effective optical path of the resonator thereby allowing the resonator to be optically tuned by controlling the piezo actuator.

In another alternative, the resonator may be coupled with an electro-optical actuator made by introducing material with a non-vanishing Pockels coefficient such as LiNbO₃ to the evanescent field of the waveguide and applying voltage such electrical field overlaps with the optical field in the LN material.

Basically, the laser system shall be applied in systems where a continuous frequency modulation shall be carried out by varying the actuation voltage to control the piezo actuator (and thereby the effective optical path length) or the electro-optical actuator. To enable a frequency-agile operation for a given optical resonator, the range of the actuation voltage shall be optimized/maximized to allow a broad range for varying or sweeping the actuation voltage.

Substantially, frequency tuning of a self-injection locking laser system with a micro-resonator which can be tuned by a piezo or electro-optical actuator coupled to or being part of the optical resonator, substantially includes the setting of a laser diode current constant or in a diode current range where self-injection locking is maintained and a variation of the actuation voltage within a tuning range is possible to vary the laser frequency output.

The laser system can be operated to attain self-injection locking via the coupling of counter-propagating optical resonator modes induced by Rayleigh backscattering.

Substantially, the variation of the actuation voltage to control the piezo or electro-optical actuator allows to operate the laser device to output laser light within a bandwidth of frequencies of the self-injection locking mode. However, along with numerous self-injection locking modes available for different laser frequency ranges, different bandwidth sizes (frequency range of a continuous self-injection locking range) can be obtained.

Therefore, it is generally desirable to operate the laser system in a self-injection locking mode while simultaneously having available an optimized/maximized bandwidth of output frequencies of laser light which can be reached within a tuning range of actuation voltages.

For tuning the laser system, firstly the laser diode current may be varied and correspondingly attained self-injection locking modes are monitored. From the monitored self-injection locking modes, laser diode current ranges in which self-injection locking is attained can be determined. The self-injection locking mode which is defined by the maximum continuous laser diode current range is selected as the selected self-injection locking range. In the selected self-injection locking range the laser frequency is locked to the frequency of the cavity resonance according to self-injection locking.

The laser diode current may be limited to a laser diode current in a center range of the laser diode current range of the selected self-injection locking mode wherein the piezo or electro-optical actuator is controlled by varying the actuation voltage to obtain the desired laser frequency output characteristics. The actuation voltage range within which the actuation voltage is varied is gradually changed in order to find a maximum operating actuation voltage range of the actuation voltage while maintaining the self-injection locked state of the selected self-injection locking range. This tuning process provides a laser diode current corresponding to the limited laser diode current and a actuation voltage range in which the self-injection locking is maintained. This setup defines the tuning characteristics by which the laser system can be operated.

Furthermore, the diode current may be set for operation of the laser system in a single line regime, the plurality of self-injection locking ranges is determined by current range of reduced cavity transmission.

Particularly, the ranges of reduced cavity transmission are detected by a measurement of a decreased cavity transmission power at an output of the at least one optical resonator, by a measurement of a decreased output power, or by a measurement of a decreased laser diode voltage.

According to embodiments, the plurality of self-injection locking ranges may be obtained by varying the laser diode current and by at least one of:
further adjusting the optical feedback phase between emitted and back-reflected light of the laser diode, particularly by setting a distance between the laser device and the at least one optical resonator;
by heating the optical resonator, and
by means of an integrated optical phase shifter between the laser device and the at least one optical resonator.

According to an alternative embodiment, the diode current may be set for operation of the laser system in a microcomb regime, wherein the plurality of self-injection locking ranges is determined by determining current ranges between start and end of a soliton step range in cavity transmission power.

Particularly, the soliton step range may be detected by a measurement of a step-like change of cavity transmission power with one or more intermediate plateaus or steps in the signal of the integrated photodiode at the back facet of the laser diode.

The advantage of generating a soliton microcomb with linear frequency chirp using the self-injection locked laser and tunable optical resonator is that due to the self injection locking principle, the laser-cavity detuning remains almost constant as the optical resonator frequency is changed by either piezoelectric or electro-optic interaction.

It may be provided that for maximizing the tuning range the following steps are iteratively carried out:
adjusting the set diode current; and
determining the maximum tuning range.

The laser device may be calibrated by coupling the laser device to the optical resonator and by adjusting the position of the laser diode with respect to an input interface of the optical resonator in order to obtain a maximum transmission through the optical resonator.

According to an embodiment, synchronous tuning of optical resonator and laser device may be made by simultaneously periodically varying of both diode current having an offset of the set diode current, and an actuation voltage with identical waveform and identical frequency while adjusting the amplitudes and relative phase of diode current and diode voltage to obtain the largest tuning range.

According to a further aspect, a control unit is provided for operating a frequency agile tunable self-injection locking laser system being formed by a laser device coupled to at least one optical resonator, wherein the control unit is configured:
to control a diode current of a laser diode of the laser device, and
to control an actuation voltage of a piezo or an electro-optical actuator configured to apply a variation of the refractive index of a resonator material through mechanical stress or an electric displacement field, respectively, at least partially onto the at least one optical resonator, inducing a change in the effective optical path length of the at least one optical resonator,
   wherein the control unit is further configured to operate the laser system with actuation voltages in a range depending on a determined maximum tuning range, wherein the maximum tuning range is determined by the steps of:
selecting a self-injection locking range among a plurality of self-injection locking ranges by varying the diode current and monitoring self-injection locking ranges, wherein self-injection locking ranges corresponding to current ranges in which self-injection locking occurs, wherein the self-injection locking corresponds to an optical feedback phase for back-reflected light from the at least one optical resonator into the laser device,
setting the diode current from the current range of the selected self-injection locking mode;
determining the maximum tuning range of the actuation voltage in which self-injection locking is maintained.

Furthermore, a frequency agile tunable self-injection locking laser system is provided, comprising:
at least one optical resonator;
a laser device coupled to the at least one optical resonator, and
the above control unit.

### BRIEF DESCRIPTION OF THE DRAWINGS

Embodiments are described in more detail in conjunction with the accompanying drawings in which:

FIG. 1 shows a schematic diagram of a laser system including a laser diode and an optical resonator.

FIG. 2 shows a cross-sectional view of the photonic resonator device configured to be stress-tuned by means of a piezo actuator.

FIGS. 3a and 3b are diagrams showing the output characteristics of a single line regime and a microcomb regime.

FIG. 4 shows a flowchart illustrating the method for operating a tunable self-injection locking laser device.

FIG. 5a shows a diagram illustrating the current ranges of reduced cavity transmission depending on different constant actuation voltages.

FIG. 5b shows the characteristics of the laser output frequency offset and the intracavity power (inverse to the cavity transmission power) depending on the diode current.

FIG. 6 shows a signal-time diagram wherein the cavity transmission, the generated light, and the direct current are illustrated for an operation in a microcomb regime.

FIG. 7 shows triangular chirp frequency pattern (top row) generated by triangular actuation of the piezo actuator operating the laser in the microcomb regime for the comb lines with different indices and its deviation of this frequency pattern (bottom row) from a perfect triangular frequency modulation.

FIG. 8 shows a diagram wherein the frequency excursion B (top panel) and the root-mean-square deviation (bottom panel) from a perfect triangular chirp pattern of the soliton microcomb light is determined as function of the comb line number.

### DETAILED DESCRIPTION OF THE EMBODIMENTS

Preferred embodiments of the invention are described in the following based on an FMCW laser device using a photonic ring oscillator as an optical resonator with a piezo actuator.

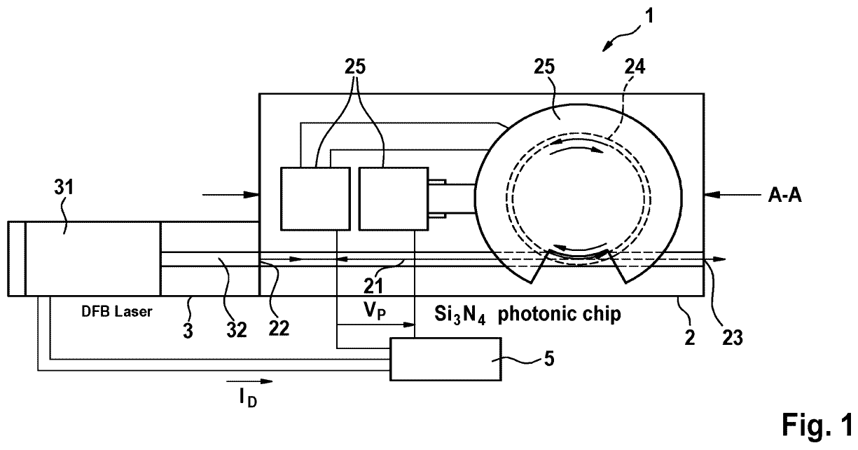

FIG. 1 shows a laser system 1 using a monolithically integrated photonic resonator device 2 (optical resonator, microresonator) optically coupled with a laser device 3, such as a DFB laser, to form a heterogeneous component. The laser system 1 may be operated via laser self-injection locking so that based on the laser power the operation scheme can transit from the single CW laser regime (i.e. linear self-injection locking) to the soliton microcomb regime and vice versa.

The laser device 3 comprises a DFB laser light source 31 in form of a laser diode with an optical waveguide 32 being optically coupled to the photonic resonator device 2. The coupling of laser light may be via a side facet of the photonic resonator device 2.

The laser light source 31 may be electrically controlled by a control unit 5 for setting a diode current I_{D} for powering the DFB laser light source 31 which allows for adjusting the output frequency and output power of the DFB laser light source 31 as well as the operation regime, i.e. a single line regime or a microcomb regime.

The laser device 3 may comprise a chip-based semiconductor laser. The optical waveguide 32 may be a linear waveguide with an end being optically coupled with the output of the semiconductor laser. The optical waveguide 32 may be made of Si₃N₄ or SiO₂ or the like.

The photonic resonator device 2 is monolithically integrated and formed on a single substrate. The substrate is preferably made of Si or SiO₂, but other materials can be applied as well. Furthermore, 7, the laser light source 31 may be fabricated on a photonic chip separate from the photonic resonator device 2 or on the same photonic chip as the photonic resonator device 2.

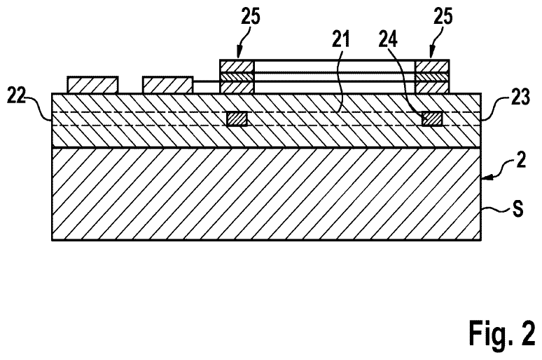

FIG. 2 additionally shows a cross-sectional view of the photonic resonator device 2.

The photonic resonator device 2 may include a common substrate S on which a waveguide 21 with a first and a second optical interface 22,23 on a lateral side of the substrate S the photonic resonator device 2 is arranged. The optical interfaces 22, 23 can be on opposite sides for a straight waveguide 21 or on the same side in case waveguide 21 is curved such as U-shaped.

The substrate S of the photonic resonator device 2 may have dimensions of about 1 mm×1 mm to 3 mm×3 mm, preferable around 2 mm×2 mm.

For laser system 1 the optical waveguide 32 of the laser device 3 may be coupled with the first optical interface 22 so as to inject laser light emitted by the laser device 3 into the photonic resonator device 2 and to guide laser light back into the DFB laser 3 to enable self-injection locking operation.

A circular resonator 24 (optical resonator) may be optically coupled with waveguide 21.

The circular resonator 24 is exemplarily shaped as a photonic ring resonator formed with Si₃N₄ in a SiO₂ layer. Such a ring resonator waveguide structure may have a diameter of around 150 to 5000 μm and an optical path length (circumference) of between 400 μm to 15500 μm. The circular resonator 24 can also have other configurations which may deviate from a ring shape such as an elliptically shaped resonator or other loop structures. Also, spirally shaped structures are possible with optical path lengths of 30 μm to 1 μm. In general, the circular resonator 24 may be made of a resonator material which has a third order (Kerr) non-linearity and an anomalous group velocity dispersion of the resonator. Using a dielectric material such as Si₃N₄ a high resonator quality Q₀>1×10⁷ can be achieved.

The optical waveguide 21 and the circular resonator 24 serve for guiding laser light emitted by the laser device 3 and are embedded in the SiO₂ layer while on the surface of the SiO₂ layer a planar piezo actuator 25 is arranged in proximity to at least a part of the circular resonator 24.

Basically, the piezo actuator 25 serves to allow a stress-optical tuning by providing a geometric deformation of the circular resonator 24 to tune its optical properties depending on an actuation voltage Vₚ. The actuation voltage Vₚ may be controlled by means of the control unit 5.

In alternative embodiments, the piezo actuator 25 can generally be replaced by an electro-optical actuator to generate an electric displacement field for an electric polarization of the resonator material depending on the actuation voltage Vₚ.

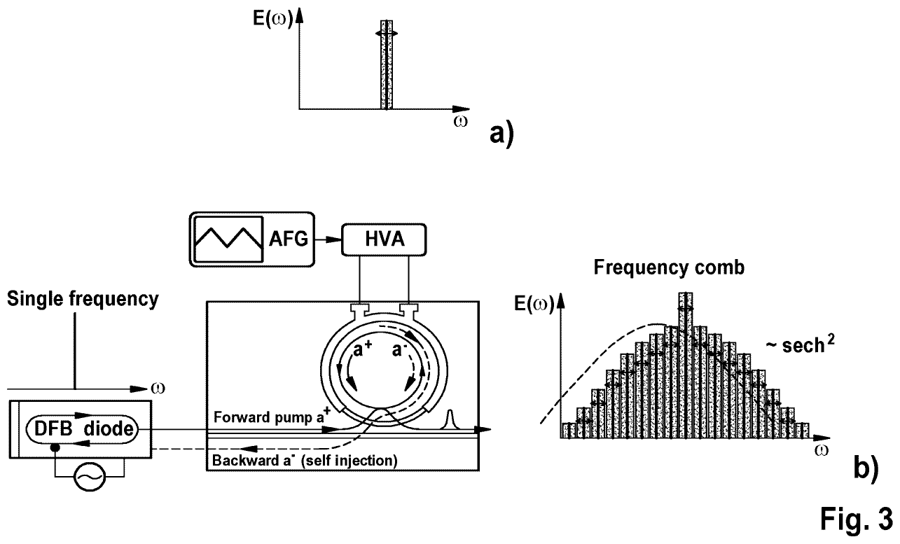

Basically, the laser device 3 of FIG. 1 can be operated in two different self-injection locking regimes, single-line regime and microcomb regime. In the single-line regime, only a single frequency emission of laser light at the output of the laser device 3 is provided as illustrated in the diagram of FIG. 3a. In the microcomb regime, the output of the laser device 3 has a spectral characteristics of an optical frequency comb, as shown in the diagram of FIG. 3b.

Both operation regimes in principle can be obtained in the same laser device 3. To achieve the microcomb regime, it has to be found the soliton supporting resonance and to tune the feedback phase to a proper value. The set laser power determines the possibility to generate a comb state by reaching a parametric threshold for comb initiation. The following a method for tuning the laser system 1 can be generally applied to both operation regimes while usually the self-injection locking range of microcomb operation mode is smaller than the self-injection locking range of the single-line operation mode.

Basically, as an initial geometrical setup (FIG. 1), the coupling of laser light from the laser device 3 to the resonator device may be made by coupling the laser light from the emitting laser diode facet to the optical waveguide 21 via e.g. tapered waveguide (inverse or outverse tapering). The output light from the end facet of the waveguide 32 is collected, and the position of the laser with respect to the photonic resonator device 2 is optimized to get a maximum laser light transmission.

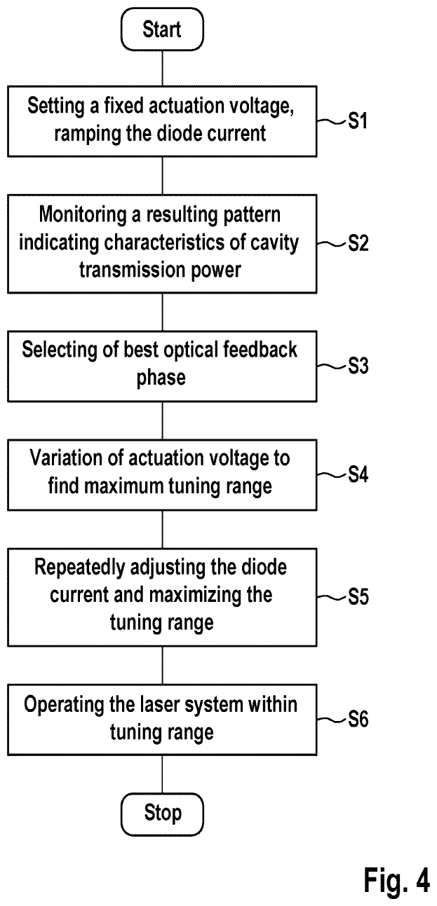

In FIG. 4, a flow chart for operating the laser system 1 in a tuned manner is shown. The method is described for tuning onto an operation in the single line regime. The method may be performed by means of the control unit 5 which is capable of providing varying diode currents I_{D} to the laser light source 31 (laser diode) and actuation voltages Vₚ to the actuator while further being configured to measure the transmission power particularly by measurement of the diode voltage.

In step S1, the actuation voltage Vₚ is set to a constant voltage within a voltage range of up to −300 to +300 V while ramping the diode current I_{D} in a given current range defined by a current offset of 100 to 300 mA with an amplitude (current range for the ramp) such as between 0 and 100 mA at a ramp frequency of between 1 to 10 MHz. The current range is selected so that at least two continuous diode current ranges are included in which self-injection locking occurs. This is carried out for a number of different setting of constant actuation voltages Vₚ. The values given herein are just exemplary for a possible device.

Other characteristics of components require different settings of electrical values.

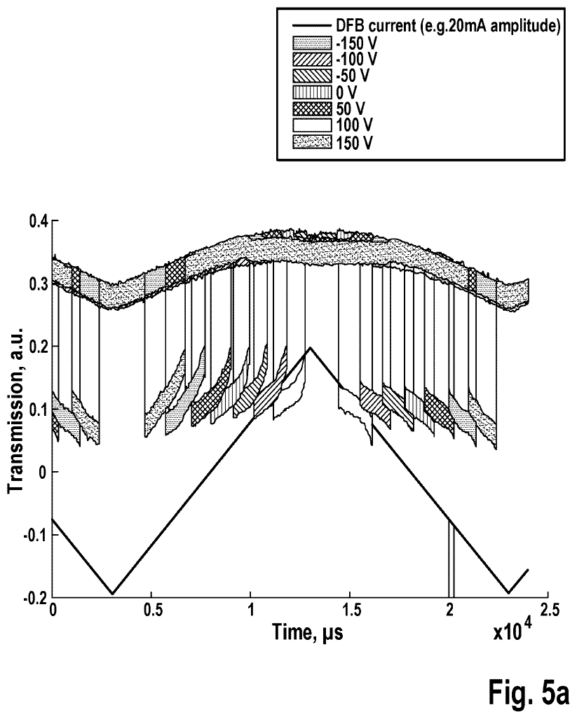

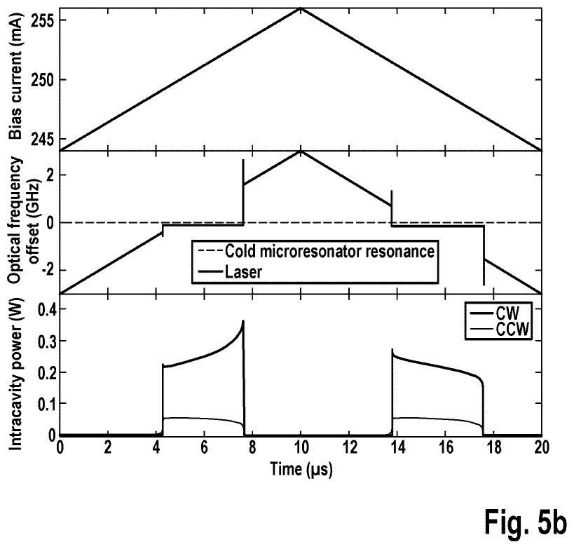

In step S2 a resulting pattern is monitored which indicates the characteristics of the cavity transmission power over the diode current I_{D} as e.g. shown in the diagram of FIG. 5a.

The diagram shows the dependency of the cavity transmission power from the laser diode currents I_{D} given various constant actuation voltages Vₚ wherein the optical feedback of a self-injection locking mode is illustrated by the ranges of reduced cavity transmission power limited by the vertical edges.

FIG. 5b shows the characteristics of the laser output frequency offset and the intracavity power (inverse to the cavity transmission power) depending on the diode current I_{D}.

In step S3, the best optical feedback phase for back-reflected light is selected which provides an optimized variation range for a frequency modulation. For selecting the best optical feedback phase, the maximum range of the laser diode current I_{D} in which a self-injection locking mode is continuously attained is selected as a maximum self-injection locking range, which is preferably the largest compared to the other self-injection locking ranges.

Further means (apart from actuation voltage Vₚ) to modify the size of the self-injection locking ranges of the self-injection locking modes can be setting the distance between the laser device 3 and the photonic resonator device 2, heating the optical resonator, and/or using at least one additional controllable phase shifters between the laser device 3 and the optical resonator 2 particularly placed on the waveguide 22 of the optical resonator 2.

In case of use of the controllable phase shifter this can be implemented by means of a thermo-optic, piezoelectric or electro-optic controllable waveguide. Alternatively, the range of phase-shift can be increased by using a strongly over-coupled micro-resonator such as a ring resonator or the like with thermal, piezoelectrical or electro-optical actuation.

Particularly, the maximum self-injection locking range of the diode current I_{D} is detected by sampling a cavity transmission over each ramping of the diode current I_{D} for the different combinations of at least one of constant actuation voltages Vₚ, the distances between the laser device 3 and the optical resonator 2, different heating temperatures of the photonic resonator device 2 and the settings of the controllable phase shifters. The cavity transmission corresponds to the laser light energy being output from the photonic resonator device 2.

Particularly, the cavity transmission can be detected by different means. Firstly, the cavity transmission can be directly measured on the output of the photonic resonator device 2 by means of an external photodiode or the like.

Furthermore, the self-injection modes can be detected by monitoring the diode voltage of the laser light source 31 (laser diode) of the laser device 3. Once the self-injection locking mode is attained, a step-like drop (high negative gradient) of the laser diode voltage can be observed. The amount of the steplike drop depends on the ring-bus waveguide coupling and may be from 5% to 95% of the cavity transmission power. Similarly, once self-injection locking mode is quit a step-like rise (high gradient) of the laser diode voltage can be observed. For a ramping of the diode current I_{D} with increasing currents the laser diode current at the step-like voltage drop indicates the start and the laser diode current I_{D} at the step-like voltage rise indicates the end of the self-injection locking mode. With this approach the self-injection locking modes can be determined without the need to directly monitor the cavity transmission power.

Once the self-injection locking mode of the optimized optical feedback phase has been selected and so the corresponding range of the laser diode current I_{D}, a linear voltage ramp is applied in step S4 onto the piezo actuator 25 basically with a frequency in the range of 1 kHz to 10 MHz and a variable amplitude. At this time, the diode current I_{D} is kept fixed at a current value in a center range of the range of the laser diode current I_{D} of the selected self-injection locking mode. Preferably, the current value is fixed to a mean current value between the start and stop current values of the range of the laser diode current of the selected self-injection locking mode.

The linear voltage ramp is preferably applied onto the piezo actuator 25 so that the mean actuation voltage Vₚ is the constant actuation voltage of the selected best optical feedback phase (see step S1) which corresponds to the selected self-injection locking mode. So, the actuation voltage Vₚ has a voltage offset and a periodic portion with a variable amplitude. The amplitude is varied, and the cavity transmission is monitored accordingly to determine maximum possible tuning range with actuators.

Basically, the maximum actuation voltage range shall be detected which allows laser frequency output modulation in the broadest possible frequency range. This can be e.g. achieved by gradually increasing the actuation voltage amplitude while simultaneously observing whether the self-injection locking state is still maintained. The actuation voltage amplitude which still allows operation in self-injection locking state corresponds to an optimized tuning range of the laser system 1.

In an optional step S5 further tuning can be achieved by slightly adjusting the diode current I_{D} (in a range of 1-2 mA or in a range lower than 1%, preferably between 0.5%-1%, of the set diode current I_{D}) and further varying the actuation voltage amplitude to further increase the tuning range of the actuation voltage Vₚ. This can be repeatedly performed.

As a result, the laser frequency tuning range of the laser system 1 is limited by the actuation voltage range in which the piezo actuator 25 can be driven without leaving the selected self-injection locking mode.

In step S6 the laser system 1 can be operated by setting all operational conditions which corresponds to the selected self-injection locking mode such as the setting of the distance between the laser device 3 and the photonic resonator device 2, the heating temperature of the optical photonic resonator device 2, or the control of the at least one additional controllable phase shifters that may be fabricated with the same process as the main actuator on the resonator. For operation the actuation voltage Vₚ can be varied within the tuning range to ensure that self-injection locking state is not lost.

When the laser system 1 shall be operated in the microcomb regime, the soliton state is formed by tuning the feedback phase by varying the diode current I_{D}. In difference to above method of searching for self-injection locking ranges with a reduced cavity transmission, a soliton step range is searched. The spectral width of the soliton step, a range of soliton existence, is always smaller than the full range of the self-injection locking.

The cavity transmission can be monitored to find a characteristic soliton step range. The soliton step range is a range where the microresonator transmission has stepwise (with two or more steps) increasing characteristics over a range of increasing diode currents I_{D}.

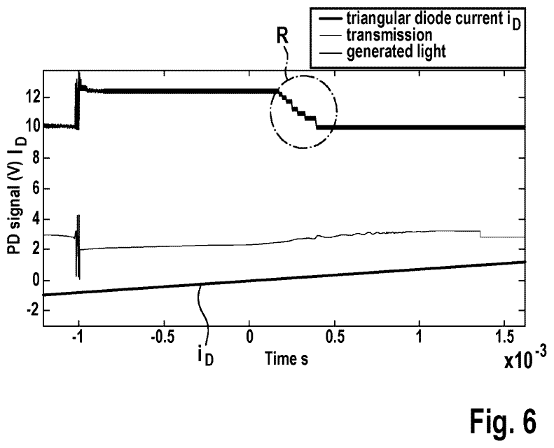

This is illustrated by the diagram of FIG. 6 which shows a signal-time diagram wherein the cavity transmission, the generated light, and the direct current are illustrated. The soliton step range R can be easily seen by the steplike figures of the cavity transmission.

Alternatively, the soliton step range can be inferred from the intensity of light generated inside the microresonator that is measured by filtering out the main laser line frequency from the microresonator transmission signal.

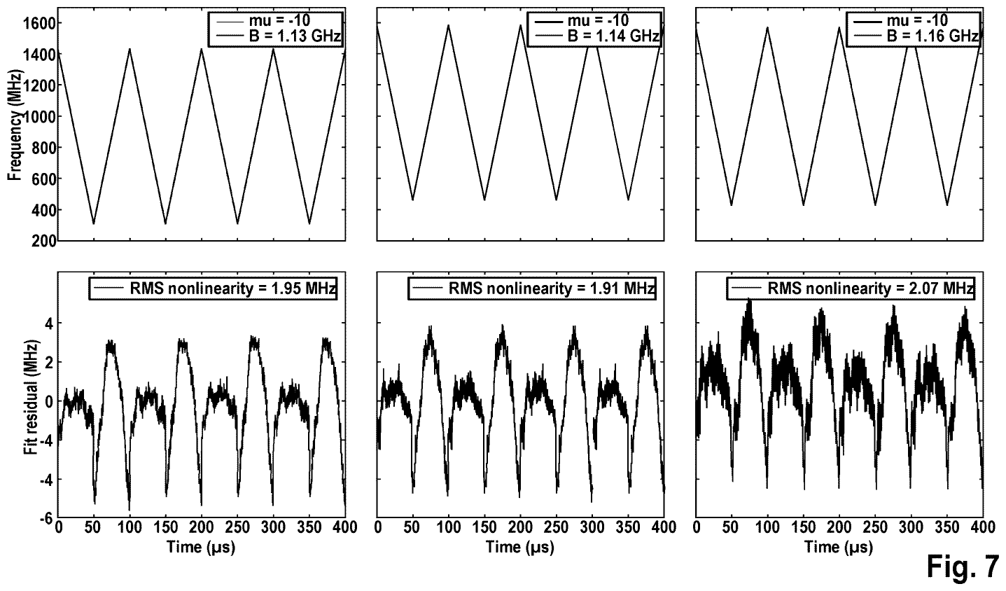

Particularly, FIG. 7 shows triangular chirp pattern generated by triangular actuation of the piezo actuator operating the laser in the microcomb regime for the comb lines with index p=−10 (left), the main laser line p=0 (middle) and p=10 (right). The top row indicates the frequency pattern that is generated in each comb line. The bottom row indicates the deviation of this frequency pattern from a perfect triangular frequency modulation.

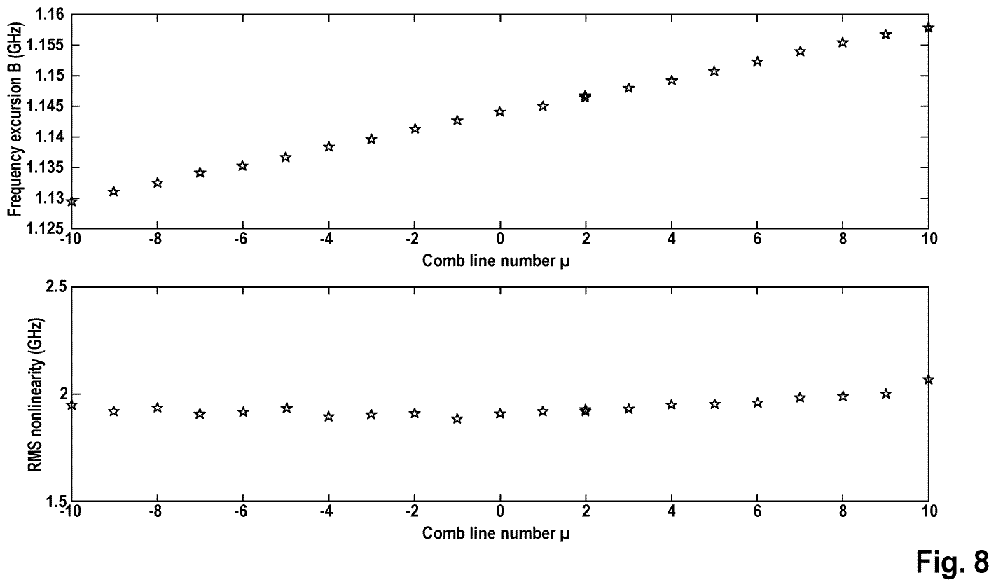

The advantage of generating a soliton microcomb with linear frequency chirp using the self-injection locked laser and tunable microresonator is that due to the self injection locking principle, the laser-cavity detuning remains almost constant as the microresonator frequency is changed by either piezoelectric or electro-optic interaction. Hence only a small variation in the frequency excursion between different comb lines is observed. FIG. 8 shows a diagram of the frequency excursion and the RMS chirp nonlinearity as function of the comb line number with the central line μ=0 representing the self-injection locked laser. The observed nonlinearity is the same for all comb lines and due to the imperfect transduction of the triangular actuation to the main laser line. It could be reduced by phase locking of any comb line or by digital predistortion of the input modulation. Compared to the prior work of Liu et al., the advantage of the self-injection locked tunable microcomb is that synchronous tuning is not required because the laser frequency follows the microresonator frequency passively due to the self-injection locking principle.

A diode current I_{D} from a center portion of the current range associated with the soliton step range, preferable the mean current value of the current values at the start and the end of the soliton step range is selected. The diode current associated therewith is fixed and the method is continued with step S4 as described above.

It is possible to extend the tuning range of actuation voltages Vₚ beyond the self-injection locking bandwidth when the diode current I_{D} and the actuation voltage Vₚ are simultaneously tuned. Therefore, two control signals for the diode current I_{D} and the actuation voltage Vₚ can be used which have an identical waveform and frequency, preferably a linear ramp. By adjusting the amplitudes and the relative phase, a mode having the highest frequency excursion of the output laser light can be obtained by observing the extend of the transmission drop in the injection locked state and the flatness of the transmission trace in the injection locked state or in the desired soliton state, preferably the single soliton state, within the self-injection locked state. The soliton state synchronous tuning is particularly beneficial due to the decreased soliton step range compared to the full self-injection locked range.

1. A method for operating a frequency agile tunable self-injection locking laser system being formed by a laser device coupled to at least one optical resonator, wherein a diode current of a laser diode of the laser device is controllable and wherein the optical resonator is controllable by controlling a piezo or an electro-optical actuator configured to apply a variation of the refractive index of a resonator material through mechanical stress or an electric displacement field, respectively, at least partially onto the at least one optical resonator depending on an actuation voltage, inducing a change in the effective optical path length of the at least one optical resonator, comprising the steps of:
selecting a self-injection locking range among a plurality of self-injection locking ranges by varying the diode current and monitoring self-injection locking ranges, wherein self-injection locking ranges corresponding to current ranges in which self-injection locking occurs, wherein the self-injection locking corresponds to an optical feedback phase for back-reflected light from the at least one optical resonator into the laser device,
setting the diode current from the current range of the selected self-injection locking mode;
determining a maximum tuning range of the actuation voltage in which self-injection locking is maintained; and
operating the laser system with actuation voltages in a range depending on the determined maximum tuning range.

2. The method according to claim 1, wherein the self-injection locking range is selected as the self-injection locking range resulting in the largest bandwidth of self-injection locking, where the laser frequency is locked to a frequency of a cavity resonance.

3. The method according to claim 1, wherein for setting the diode current, the diode current is selected from a central range between the current limits of the selected self-injection locking range, wherein the set as a mean current of the current limits of the selected self-injection locking range.

4. The method according to claim 1, wherein the diode current is set for operation of the laser system in a single line regime, the plurality of self-injection locking ranges is determined by current range of reduced cavity transmission.

5. The method according to claim 4, wherein the ranges of reduced cavity transmission are detected by a measurement of a decreased cavity transmission power at an output of the at least one optical resonator, by a measurement of a decreased diode power, or by a measurement of a decreased diode voltage.

6. The method according to claim 1, wherein the plurality of self-injection locking ranges are obtained by varying the laser diode current and by at least one of:
further adjusting the optical feedback phase between emitted and back-reflected light of the laser diode, particularly by setting a distance between the laser device and the at least one optical resonator;
by heating the at least one optical resonator, and
by means of an optical phase shifter between the laser device and the at least one optical resonator.

7. The method according to claim 1, wherein the diode current is set for operation of the laser system in a microcomb regime, wherein the plurality of self-injection locking ranges is determined by determining current ranges between start and end of a soliton step range in cavity transmission power.

8. The method according to claim 7, wherein the soliton step range are detected by a measurement of a step-like change of laser diode voltage with one or more intermediate plateaus of cavity transmission power.

9. The method according to claim 1, wherein for maximizing the tuning range the following steps are iteratively carried out:
adjusting the set diode current; and
determining the maximum tuning range.

10. The method according to claim 1, wherein the laser device is calibrated by coupling the laser device to the at least one optical resonator and by adjusting the position of the laser diode with respect to an input interface of the at least one optical resonator in order to obtain a maximum transmission through the at least one optical resonator.

11. The method according to claim 1, wherein synchronous tuning of the at least one optical resonator and laser device is made by simultaneously periodically varying of both diode current having an offset of the set diode current, and an actuation voltage with identical waveform and identical frequency while adjusting the amplitudes and relative phase of diode current and diode voltage to obtain the largest tuning range keeping the laser in self-injection locked state.

12. The method according to claim 1, where the continuous actuation voltage is composed of a linear ramp or a set of linear ramps within the self-injection locking range.

13. The method according to claim 1, where the repetition frequency of the linear ramps is equal to or greater than 100 kHz.

14. A control unit for operating a frequency agile tunable self-injection locking laser system being formed by a laser device coupled to at least one optical resonator, wherein the control unit is configured:
to control a diode current of a laser diode of the laser device, and
to control an actuation voltage of a piezo or an electro-optical actuator configured to apply a variation of the refractive index of a resonator material through mechanical stress or an electric displacement field, respectively, at least partially onto the at least one optical resonator, inducing a change in the effective optical path length of the at least one optical resonator,
wherein the control unit is further configured to operate the laser system with actuation voltages in a range depending on a determined maximum tuning range, wherein the maximum tuning range is determined by the steps of:
selecting a self-injection locking range among a plurality of self-injection locking ranges by varying the diode current and monitoring self-injection locking ranges, wherein self-injection locking ranges corresponding to current ranges in which self-injection locking occurs, wherein the self-injection locking corresponds to an optical feedback phase for back-reflected light from the at least one optical resonator into the laser device,
setting the diode current from the current range of the selected self-injection locking mode; and
determining the maximum tuning range of the actuation voltage in which self-injection locking is maintained.

15. A frequency agile tunable self-injection locking laser system comprising:
at least one optical resonator;
a laser device coupled to the at least one optical resonator, and
a control unit according to claim 14.
